(19) United States
(12) Patent Application Publication
(10) Pub. No.: US 2023/0024253 A1
(43) Pub. Date: Jan. 26, 2023

(54) SEMICONDUCTOR DEVICE AND METHOD FOR FORMING SAME

(71) Applicant: CHANGXIN MEMORY TECHNOLOGIES, INC., Hefei City (CN)

(72) Inventor: Mengzhu QIAO, Hefei City (CN)

(73) Assignee: CHANGXIN MEMORY TECHNOLOGIES, INC., Hefei City (CN)

(21) Appl. No.: 17/936,848

(22) Filed: Sep. 29, 2022

(30) Foreign Application Priority Data
May 31, 2022 (CN) 202210609534.9

(51) Int. Cl. H01L 27/108

(52) U.S. Cl. CPC H01L 27/10805; H01L 27/10891

(57) ABSTRACT

A semiconductor device includes a semiconductor substrate and word line structures. A plurality of active areas are formed in the substrate, and the plurality of active areas are isolated by an isolation structure. The isolation structure includes first areas and second areas. A dimension of the second areas is larger than that of the first areas in first direction. The word line structures are below a surface of the substrate and extend in first direction. The word line structures penetrate the isolation structure and the plurality of active areas. A word line structure includes first sub-word line structures located in first areas and second sub-word line structures located in second areas. The first sub-word line structures have first dimension in second direction, and the second sub-word line structures have second dimension at least larger than first dimension in second direction. The second direction forms an included angle with first direction.

### CROSS-REFERENCE TO RELATED APPLICATION

The present application claims priority to Chinese Patent Application No. 202210609534.9 filed on May 31, 2022, the disclosure of which is hereby incorporated by reference in its entirety.

### BACKGROUND

Dynamic random access memory (DRAM) is a semiconductor device commonly used in computers. DRAM is composed of several storage cells. Each storage cell typically includes a transistor and a capacitor. The capacitor is electrically connected to one end of the transistor, such as a drain (or a source). A bit line is electrically connected to the other end of the transistor, such as the source (or the drain), and the gate of the transistor is connected to a word line. With the increasing density of semiconductor devices, devices in storage cells exhibit shrinking physical volumes. For example, the reduction in the dimensions of data lines (word lines or bit lines) increases the resistances of data lines, thereby affecting switching efficiency of transistors of the storage cells, and thus reducing reading and writing performance of semiconductor devices, and in severe cases, even affecting reliability of semiconductor devices. Therefore, how to improve the performance of semiconductor devices has become an urgent problem to be solved.

### SUMMARY

The disclosure relates to the technical field of semiconductors, and relates to, but is not limited to, a semiconductor device and a method for forming the same.

Embodiments of the disclosure provide a semiconductor device including a semiconductor substrate and a plurality of word line structures.

A plurality of active areas are formed in the semiconductor substrate, and the plurality of active areas are isolated by an isolation structure. The isolation structure includes a plurality of first areas and a plurality of second areas. A dimension of a given one of the plurality of second areas in a first direction is larger than a dimension of a given one of the plurality of first areas in the first direction.

The plurality of word line structures are located below a surface of the substrate and extend in the first direction. The plurality of word line structures cross through the isolation structure and the plurality of active areas. A given one of the plurality of word line structures includes a first sub-word line structure located in a given one of the first areas and a second sub-word line structure located in a given one of the second areas. The first sub-word line structure has a first dimension in a second direction, and the second sub-word line structure has a second dimension at least larger than the first dimension in the second direction. An included angle is formed between the second direction and the first direction.

The embodiments of the disclosure also provide a method for forming a semiconductor device, including the following operations.

A semiconductor substrate is provided. A plurality of active area are formed in the semiconductor substrate, and the plurality of active areas are isolated by an isolation structure. The isolation structure includes a plurality of first areas and a plurality of second areas. A dimension of a given one of the plurality of second areas in a first direction is larger than a dimension of a given one of the plurality of first areas in the first direction.

A first etching operation is performed to form a first trench in the plurality of first areas and the plurality of second areas.

A second etching operation is performed on the first trench in a given one of the plurality of second areas to widen an opening of the first trench so as to form a second trench. The first trench has a first dimension in a second direction, and the second trench has a second dimension at least larger than the first dimension in the second direction.

A word line structure is formed in the first trench and the second trench. The first direction is an extension direction of the word line structure, an included angle is formed between the second direction and the first direction.

### BRIEF DESCRIPTION OF THE DRAWINGS

FIG. 1A is a planar diagram of a semiconductor device provided by an embodiment of the disclosure.

FIG. 1B is a schematic local sectional diagram along a line A-A′ shown in FIG. 1A.

FIG. 1C is a schematic local sectional diagram along a line B-B′ shown in FIG. 1A.

FIG. 2 is a schematic flowchart of the method for forming a semiconductor device provided by an embodiment of the disclosure.

FIG. 3A is a schematic planar diagram of forming first trenches provided by an embodiment of the disclosure.

FIG. 3B is a schematic local sectional diagram along a line A-A′ shown in FIG. 3A.

FIG. 3C is a schematic local sectional diagram along a line B-B′ shown in FIG. 3A.

FIG. 3D is a schematic planar diagram of forming a mask provided by an embodiment of this disclosure.

FIG. 3E is a schematic local sectional diagram along a line A-A′ shown in FIG. 3D.

FIG. 3F is a schematic local sectional diagram along a line B-B′ shown in FIG. 3D.

FIG. 3G is a schematic planar diagram of forming second trenches provided by an embodiment of the disclosure.

FIG. 3H is a schematic local sectional diagram along a line A-A′ shown in FIG. 3G.

FIG. 3I is a schematic local sectional diagram along a line B-B′ shown in FIG. 3G.

FIG. 3J is a schematic planar diagram of forming conductive layers provided by an embodiment of this disclosure.

FIG. 3K is a schematic local sectional diagram along a line A-A′ shown in FIG. 3J.

FIG. 3L is a schematic local sectional diagram along a line B-B′ shown in FIG. 3J.

FIG. 3M is a schematic planar diagram of forming trenches after a back etching operation provided by an embodiment of the disclosure.

FIG. 3N is a schematic local sectional diagram along a line A-A′ shown in FIG. 3M.

FIG. 3O is a schematic local sectional diagram along a line B-B′ shown in FIG. 3M.

### DETAILED DESCRIPTION

The technical solution of the disclosure will be further explained in detail below with reference to the drawings and the embodiments. Although exemplary implementation modes of the disclosure are shown in the drawings, it is to be understood that the disclosure may be embodied in various forms and should not be limited by the implementation modes set forth herein. On the contrary, these embodiments are provided to enable a more thorough understanding of the disclosure and to fully convey the scope of the disclosure to those skilled in the art.

The disclosure is described in more detail by way of example with reference to the drawings in the following paragraphs. The advantages and features of the disclosure will become clearer from the following description and claims. It is to be noted that the drawings are presented in a very simplified form with inaccurate scales, and are only for the purpose of conveniently and clearly assisting in illustrating the embodiments of the disclosure.

It is to be understood that spatial relational terms such as “below”, “under”, “lower”, “beneath”, “above”, and “upper” etc. may be used herein for convenience of describing to describe a relationship between one element or feature and another element or feature illustrated in the figures. It is to be understood that, in addition to the orientation shown in the figures, the spatially relational terms are intended to further include different orientations of devices in use and operation. For example, if the devices in the figures are turned over, elements or features described as being “under” or “beneath” or “below” other elements or features will be oriented to be “on” the other elements or features. Therefore, the exemplary terms “under” and “below” may include both upper and lower orientations. Moreover, the device may include otherwise orientation (rotation by 90 degrees or in other orientations) and the spatial descriptors used herein may be interpreted accordingly.

The terminology used herein is intended to describe the specific embodiments only and is not to be a limitation of the disclosure. As used herein, singular forms “a”, “an” and “said/the” are also intended to include the plural forms, unless the context clearly indicates otherwise. It should also be understood that the terms “consist . . . of” and/or “include”, when used in this specification, determine the presence of said features, integers, steps, operations, elements and/or components, but do not exclude the presence or addition of one or more other features, integers, steps, operations, elements, components and/or groups. As used herein, the term “and/or” includes any and all combinations of related listed items.

It is to be noted that the technical solution described in the embodiments of this disclosure can be combined arbitrarily without conflict.

As described in the background, how to improve switching efficiency of transistors of storage cells to improve the performance of semiconductor memory devices has become an urgent technical problem to be solved.

In this regard, the disclosure proposes the following implementation modes.

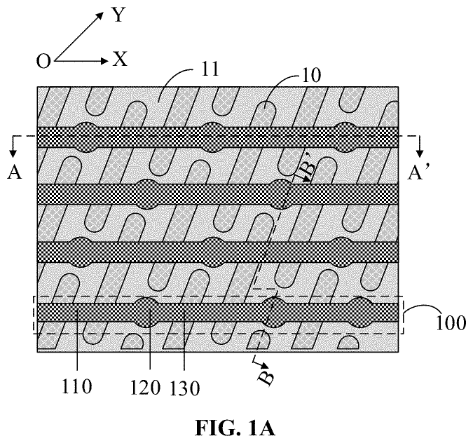

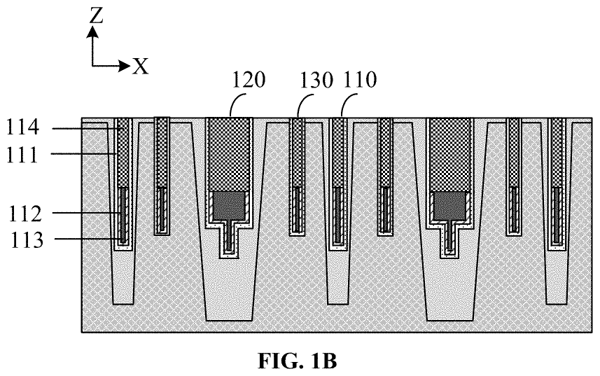

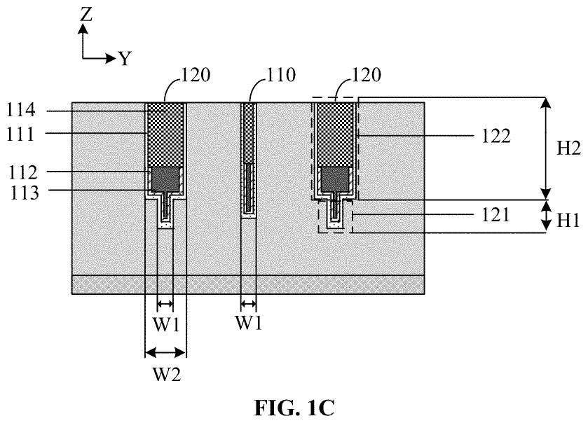

The embodiments of the disclosure provide a semiconductor device. FIG. 1A is a schematic planar diagram of a semiconductor device provided by an embodiment of the disclosure. FIG. 1B and FIG. 1C are schematic local sectional diagrams along a line A-A′ and along a line B-B′ shown in FIG. 1A, respectively. As shown in FIG. 1A to FIG. 1C, the semiconductor device includes a semiconductor substrate and a plurality of word line structures.

A plurality of active areas 10 are formed in the semiconductor substrate, and the plurality of active areas 10 are isolated by an isolation structure 11. The isolation structure 11 includes a plurality of first areas and a plurality of second areas. A dimension of a given one of the plurality of second areas in a first direction is larger than a dimension of a given one of the plurality of first areas in the first direction. The plurality of word line structures 100 are located below a surface of the substrate and extend in the first direction. The plurality of word line structures cross through the isolation structure 11 and the plurality of active areas 10. A given one of the plurality of word line structures includes a first sub-word line structure 110 located in a given one of the first areas and a second sub-word line structure 120 located in a given one of the second areas. The first sub-word line structure 110 has a first dimension in a second direction. The second sub-word line structure 120 has a second dimension at least larger than the first dimension in the second direction. An included angle is formed between the second direction and the first direction. Here, the first direction is X direction, and the second direction is Y direction.

In the embodiments of the disclosure, the plurality of active areas 10 are arranged alternately and at intervals in the second direction. The included angle between the first direction and the second direction is greater than 30 degrees. In a specific implementation mode, the included angle between the first direction and the second direction may be 60 degrees.

It is to be noted that the schematic planar diagram shown in FIG. 1A is only an example. In other embodiments, according to parameter requirements of semiconductor devices, active areas may also be arranged in other arrangements, and the protection scope of this disclosure should not be unduly limited here.

In some embodiments, the plurality of first areas and the plurality of second areas are arranged alternately and at intervals in the first direction.

Specifically, the semiconductor substrate may be a simple semiconductor material substrate (for example, silicon substrate, germanium substrate, or the like), a composite semiconductor material substrate (for example, germanium silicon substrate, or the like), or a silicon on insulator (SOI), germanium on insulator (GeOI) substrate, or the like.

In a specific implementation mode, the material of the active areas 10 may be silicon, and the active areas 10 may be formed by an epitaxial process. In another example, N-type active areas or P-type active areas may also be formed by doping the semiconductor substrate.

In some embodiments, the material of the isolation structure 11 may be silicon oxide, silicon oxynitride or other suitable insulating material, and the isolation structure 11 may be a shallow trench isolation (STI) structure.

In the embodiments of the disclosure, in the second direction, a second sub-word line structure 120 includes a first portion 121 having the first dimension and a second portion 122 having the second dimension.

The second portion 122 is located above the first portion 121.

In some embodiments, a ratio of the second dimension to the first dimension is in a range of 1.2-3. Referring to FIG. 1C for details, W2 is a width of a second portion 122 of a second sub-word line structure 120 in the second direction, that is, the second dimension. W1 is a width of a first sub-word line structure 110 in the second direction, that is, the first dimension. W1 is also a width of a first portion 121 of the second sub-word line structure 120 in the second direction. The ratio of W2 to W1 is in the range of 1.2-3. Since the second sub-word line structure 120 has at least a width in the second direction larger than a width of the first sub-word line structure 110 in the second direction, an overall sectional area of the word line structure is increased, thereby reducing a resistance of the word line structure.

In other embodiments, both the first portion and the second portion of the second sub-word line structure have a second dimension in the second direction, that is, the first portion and the second portion have the same width in the second direction. The second sub-word line structure having such a shape has a dimension larger than that of the first sub-word line structure in the second direction, which can effectively reduce the resistance of the word line structure and thus improve the switching efficiency of the transistor.

In some embodiments, a height ratio of the second portion 122 to the first portion 121 in the direction perpendicular to substrate is in a range of 0.5 to 10. Referring to FIG. 1C for details, H2 is the height of the second portion 122 of the second sub-word line structure 120 in the direction perpendicular to substrate, and H1 is the height of the first portion 121 of the second sub-word line structure 120 in the direction perpendicular to substrate. The ratio of H2 to H1 is in range of 0.5 to 10.

In the embodiments of the disclosure, a given one of the plurality of word line structure further includes a third sub-word line structure 130 located in a given one of the plurality of active areas 10. The third sub-word line structure 130 has a third dimension in the second direction. The third dimension is a width of the third sub-word line structure 130 in the second direction, and the third dimension is less than or equal to the first dimension.

In a specific implementation mode, referring to FIG. 1B, the first sub-word line structure 110, the second sub-word line structure 120, and the third sub-word line structure 130 each includes a first liner 111, a second liner 112, a conductive layer 113, and an isolation material layer 114. The isolation material layer 114 is located over the conductive layer 113 and covers a surface of the conductive layer 113. Specifically, the first liner 111 may be an oxide layer or has other dielectric material with a high dielectric constant. A material of the second liner 112 may be titanium nitride. A material of the conductive layer 113 may be a metal, such as metallic tungsten. A material of the isolation material layer 114 may be silicon nitride.

In some embodiments, referring to FIG. 1B, a depth of the third sub-word line structure 130 is less than or equal to a depth of the first sub-word line structure 110, and the depth of the first sub-word line structure 110 is less than a depth of the second sub-word line structure 120. Here, the depths refer to depths in a Z direction.

In some embodiments, a source and a drain are formed in an active area at either side of the word line structure. A gate connected with the word line structure or the word line structure itself as the gate constitutes a metal-oxide-semiconductor field-effect transistor (MOSFET) of a storage cell with a source region and a drain region jointly. Further, the source region is connected to a bit line. A storage capacitor is formed above the drain region, and a lower plate of the storage capacitor is electrically connected to the drain region. Thus, a semiconductor memory, such as DRAM, and of course other types of memories, may be formed.

In some embodiments, the semiconductor device is a three-dimensional dynamic random access memory, such as DRAM.

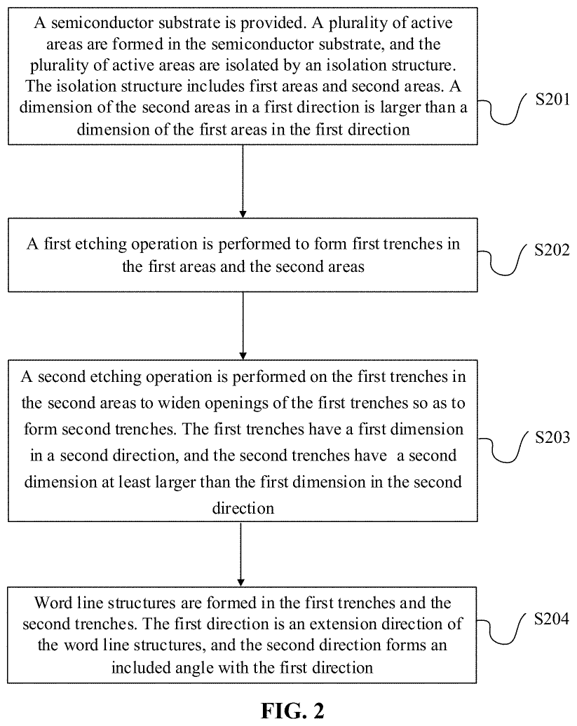

An embodiment of the disclosure also provides a method for forming a semiconductor device. FIG. 2 is a schematic flowchart of the method for forming a semiconductor device provided by the embodiment of the disclosure. The specific operations of the method for forming a semiconductor device include the following ones.

In S201, a semiconductor substrate is provided. A plurality of active areas are formed in the semiconductor substrate, and the plurality of active areas are isolated by an isolation structure. The isolation structure includes a plurality of first areas and a plurality of second areas. A dimension of a given one of the plurality of second areas in a first direction is larger than a dimension of a given one of the plurality of first areas in the first direction.

In S202, a first etching operation is performed to form a first trench in the plurality of first areas and the plurality of second areas.

In S203, a second etching operation is performed on the first trench in a given one of the plurality of second areas to widen an opening of the first trench so as to form a second trench. The first trench has a first dimension in a second direction, and the second trench has a second dimension at least larger than the first dimension in the second direction.

In S204, a word line structure is formed in the first trench and the second trench. The first direction is an extension direction of the word line structure, and an included angle is formed between the second direction and the first direction.

In the embodiment of the disclosure, the plurality of active areas 10 are arranged alternately and at intervals in the second direction. The included angle between the first direction and the second direction is greater than 30 degrees. In a specific implementation mode, the included angle between the first direction and the second direction may be 60 degrees.

In some embodiments, a formation process of the active areas 10 is as follows. A first mask layer (not shown) is formed on a semiconductor substrate. The first mask layer has several first openings distributed in parallel. Then, the semiconductor substrate is etched along the first openings with the first mask layer as a mask to form several discrete strip-shaped areas in the semiconductor substrate. A first area is provided between adjacent strip-shaped areas. The strip-shaped areas are then etched to form second areas in the strip-shaped areas. The second areas divide each strip-shaped area into plurality of active areas.

In some embodiments, the formation process of the isolation structure 11 includes the following operations. An isolation material layer covering the active areas 10 is formed, in which the isolation material layer fills up the first areas and the second areas. Then the isolation material layer above top surfaces of the active areas is removed by planarization to form the isolation structure in the first areas and the second areas. A top surface of the isolation structure is flush with the top surfaces of the active area.

In the embodiment of the disclosure, the plurality of first areas and the plurality of second areas are arranged alternately and at intervals in the first direction.

In some embodiments, a material of the isolation structure 11 may be silicon oxide, silicon oxynitride or other suitable insulating material. The isolation structure 11 may be an STI structure.

In other embodiments, the active areas 10 may be formed by an epitaxial process, and a material of the active areas 10 may be silicon. In another example, N-type active areas or P-type active areas may also be formed by doping the semiconductor substrate.

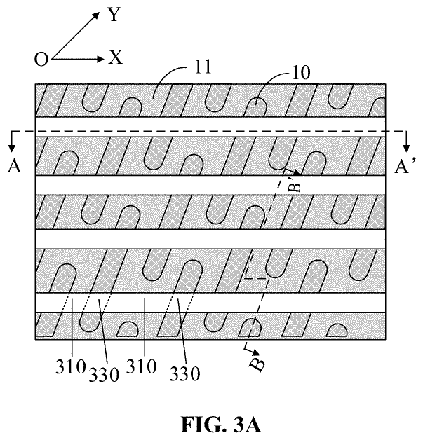

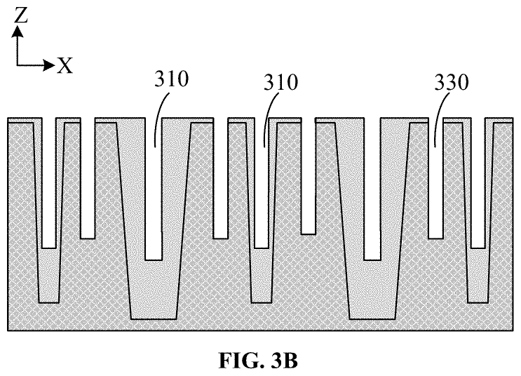

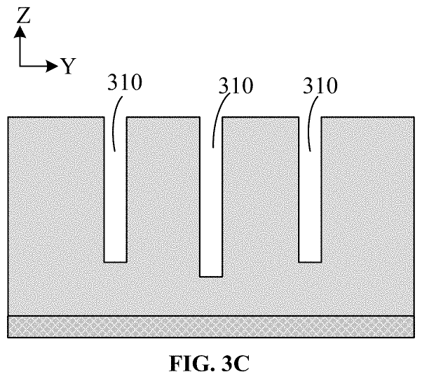

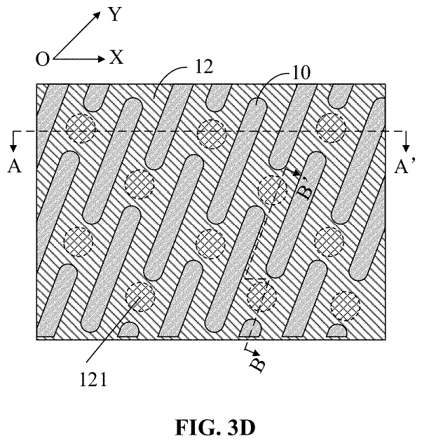

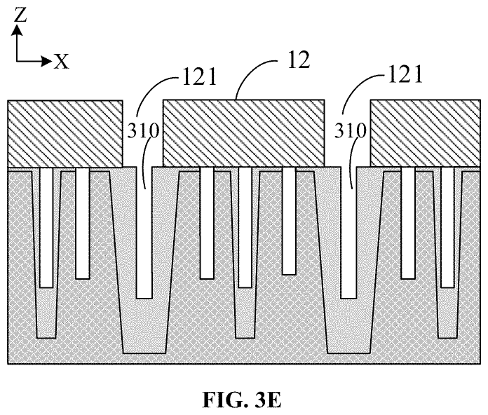

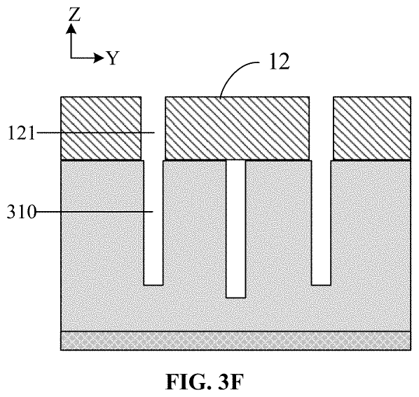

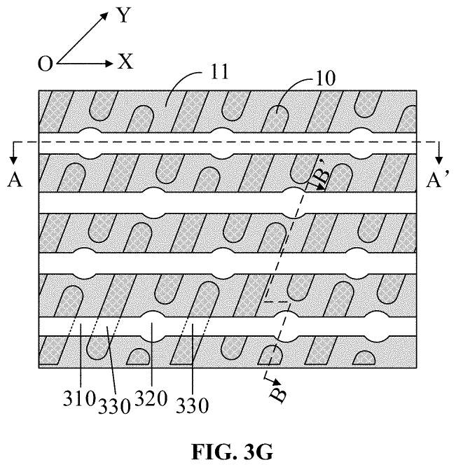

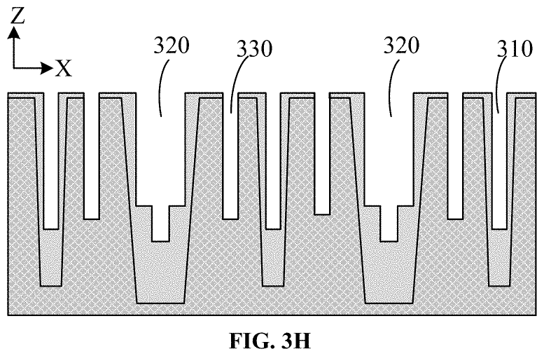

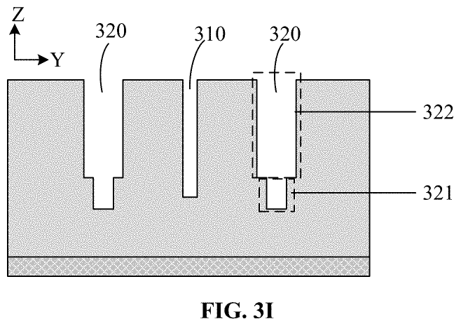

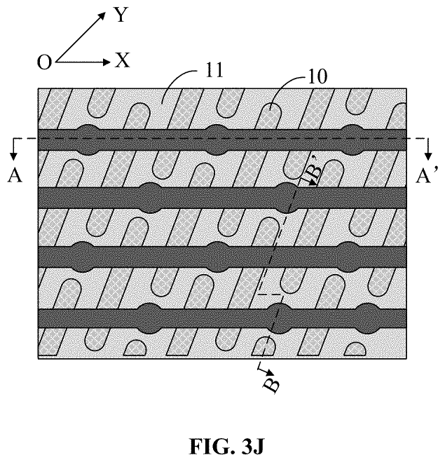

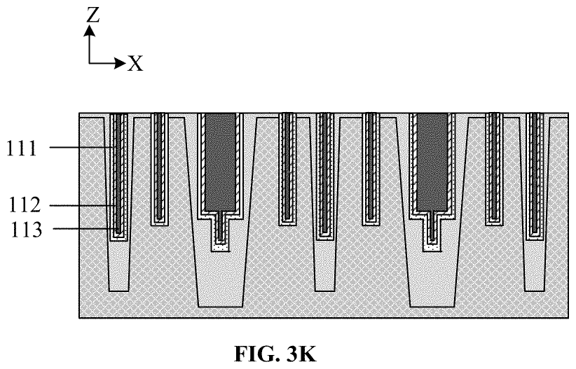

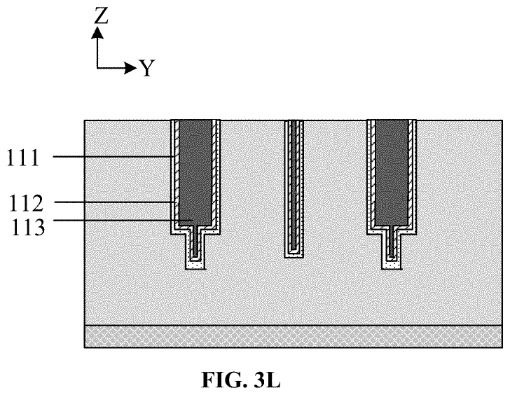

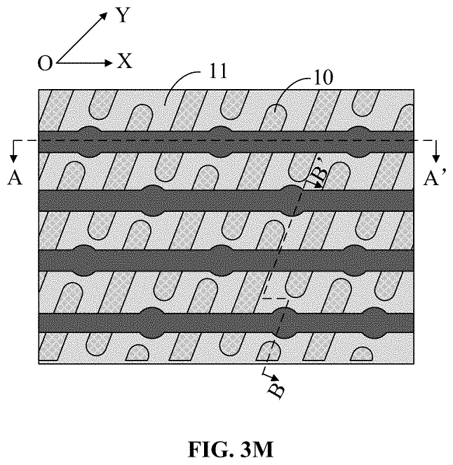

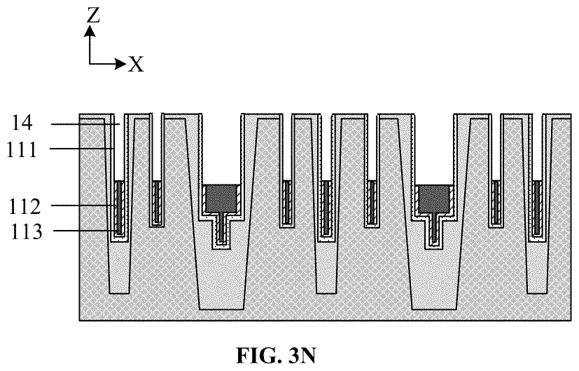

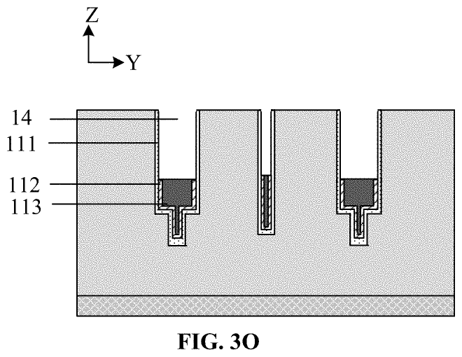

FIG. 3A to FIG. 3O are schematic local structural diagrams of a process for forming a semiconductor device provided by an embodiment of the disclosure. The method for forming a semiconductor device of the embodiment is described below with reference to FIG. 2 and FIG. 3A to FIG. 3O.

Referring to FIG. 3A to FIG. 3C, part of an active area and part of the isolation structure are etched by the first etching operation to form a first trench 310 in the plurality of first areas and the plurality of second areas, and a third trench 330 in a given one of the plurality of active areas. Actually, each trench formed by performing the first etching operation includes the first trenches 310 located in the first areas and the second areas and the third trenches 330 located in the active areas. Here, an anisotropic plasma etching process can be used. In an embodiment, the etching gas employed in the anisotropic plasma etching process includes one or more a combination of more of Cl₂, HBr, CF₄, or CHF₃. In other embodiments, the etching gas employed in the anisotropic plasma etching process operation also includes one or a combination of more of helium or argon. FIG. 3A is a schematic planar diagram of forming the first trenches. FIG. 3B and FIG. 3C are schematic local sectional diagrams along the line A-A′ and along the line B-B′, respectively, shown in FIG. 3A. Here, a direction of the line A-A′ is the first direction, and a direction of the line B-B′ is the second direction.

In some embodiments, referring to FIG. 3B and FIG. 3C, a depth of the third trench 330 is less than or equal to a depth of the first trench 310 in a given one of the plurality of first areas, and the depth of the first trench 310 in a given one of the plurality of first areas is less than a depth of the first trench 310 in a given one of the plurality of second areas. Here, the depths refer to depths in the Z direction.

In some embodiments, the depths of the first trench in a given one of the plurality of first areas, the first trench in a given one of the plurality of second areas and the third trench in the Z direction can be controlled by parameters of the etching process (for example, etching time, gas flow rate, ratio, pressure, temperature, and the like). For example, when the etching rate is constant, the longer the etching time is, the deeper the trenches formed is in the Z direction.

Referring to FIG. 3D to FIG. 3F, a patterned mask layer 12 is formed. The patterned mask layer has multiple openings 121, a given one of which exposes a surface of a given one of the plurality of second areas and the first trench 310 in the given one of the plurality of second areas. FIG. 3D is a schematic planar diagram of forming the patterned mask layer, and FIG. 3E and FIG. 3F are schematic local sectional diagram along a line A-A′ and along a line B-B′, respectively, shown in FIG. 3D.

A material of the mask layer 12 may be one or more of silicon oxide, silicon nitride, or silicon oxynitride. The mask layer 12 may be a single-layer or multi-layer stacked structure.

In some embodiments, the mask layer 12 includes a silicon nitride layer and an amorphous carbon layer on the silicon nitride layer. In a specific implementation mode, the silicon nitride layer and the amorphous carbon layer may be formed by chemical vapor deposition (CVD), physical vapor deposition (PVD), atomic layer deposition (ALD), or any combination thereof.

In some embodiments, the formation process of the patterned mask layer 12 includes the following operations. A photoresist layer (not shown) is first formed on the mask layer, then are exposed and developed to form a patterned photoresist layer having multiple lithography openings, and finally the mask layer 12 is etched with the patterned photoresist layer as a mask to form multiple openings 121 in the mask layer 12. The positions of the lithography openings are in one-to-one correspondence to the positions of the openings 121. In a specific implementation mode, the mask layer 12 may be etched by an anisotropic plasma etching process.

Referring to FIG. 3G to FIG. 3I, the first trench 310 in the given one of the plurality of second areas are etched along the given one of the plurality of openings 121 to form the second trench 320 in a given one of the plurality of second areas. The first trench 310 has a first dimension in the second direction. The second trench 320 has a second dimension at least larger than the first dimension in the second direction. The third trench 330 has a third dimension in the second direction. The third dimension is less than or equal to the first dimension. FIG. 3G is a schematic planar diagram of forming the second trenches. FIG. 3H and FIG. 3I are schematic local sectional diagrams along a line A-A′ and along a line B-B′, respectively, shown in FIG. 3G.

In some embodiments, in the Y direction, as shown in FIG. 3I, a second trench 320 includes a lower trench portion 321 having the first dimension and an upper trench portion 322 having the second dimension in communication with the lower trench portion. Specifically a depth ratio of the upper trench portion 322 to the lower trench portion 321 in a direction perpendicular to the substrate is in a range of 0.5 to 10.

In the embodiments of the disclosure, a ratio of the second dimension to the first dimension is in a range of 1.2 to 3. Referring to FIG. 3I for details, a width of a upper trench portion 322 of the second trench 320 in the second direction is the second dimension, a width of a lower trench portion 321 of the second trench 320 in the second direction is the first dimension. Moreover, a width of the first trench in the second direction is also the first dimension. The ratio of the second dimension to the first dimension is in a range of 1.2 to 3. Since the second trenches 320 has at least a width larger than that of the first trench 310 in the second direction, word line structures with an increased sectional area can be formed in subsequent process operations. In other embodiments, by adjusting parameters of the second etching process, for example, controlling a depth of the second etching operation to be equal to a depth of the first trenches in the second areas, both a upper trench portion and a lower trench portion of the second trench have the second dimension in the second direction, that is, the upper trench portion and the lower trench portion have a same width in the second direction. A second trench having the shape has a dimension larger than that of a first trench in the second direction, which facilitates to form a word line structure with a smaller resistance in subsequent process operations.

Referring to FIG. 3J to FIG. 3L, a first liner 111 and a second liner 112 are sequentially formed on inner walls of the first trench 310, the second trench 320 and the third trench 330. The first trench 310, the second trench 320 and the third trench 330 are filled to form a conductive layer 113. FIG. 3J is a schematic planar diagram of forming the conductive layers. FIG. 3K and FIG. 3L are schematic local sectional diagrams along a line A-A′ and along a line B-B′, respectively, shown in FIG. 3J.

The first liners 111 may be an oxide layer, or have another dielectric material with a high dielectric constant. In an embodiment, an oxide layer may be formed as the first liner 111 on the inner walls of the first trench, the second trench, and the third trench by a thermal oxidation process. In another embodiment, it is also possible to grow an oxide layer as the first liner 111 in a high-temperature water vapor atmosphere, by an In-Situ Steam Generation (ISSG) method. The oxide layer can grow faster by the method, and the oxide layer generated by the in-situ water vapor generation method has better electrical properties. In other embodiments, the first liner 111 may also be formed by a deposition process, such as CVD, PVD, ALD or any combination thereof. Second liners, conductive layers and the like described below can also be fabricated using a similar deposition method, so the deposition method of each film layer will not be described in the description of the formation method of the word line structure below.

After the first liner 111 is formed, the second liner 112 is continuously filled into the first trench, the second trench and the third trench. Specifically the material of the second liner 112 includes, but is not limited to, titanium nitride or tantalum nitride.

After the second liner 112 is formed, a conductive layer 113 is continuously filled in the first trench, the second trench and the third trench by a deposition process. The material of the conductive layer 113 may be a metal, such as tungsten.

Referring to FIG. 3M to FIG. 3O, a back etching operation is performed on the second liner and the conductive layer to remove part of the second liner 112 and part of the conductive layer 113 in the first trench, the second trench and the third trench. FIG. 3M is a schematic planar diagram of forming the trenches 14 by etching back. FIG. 3N and FIG. 3O are schematic local sectional diagrams along a line A-A′ and along a line B-B′ shown in FIG. 3M, respectively.

In some embodiments, a second liner 112 covers the inner walls of the first trench, the second trench and the third trench. A conductive layer 113 fills up the first trench, the second trench and the third trench. An upper surface of the conductive layer 113 is flush with that of the second liner 112. Then, the second liner 112 and the conductive layer 113 are etched back to form the trenches 14, reducing heights of the second liner 112 and the conductive layer 113 as shown in FIG. 3N and FIG. 3O. An etching depth of the back etching operation is smaller than an etching depth of the second etching operation. The etching depth can be controlled by parameters of the etching process (such as etching time, gas flow rate, ratio, pressure, temperature, and the like). In a specific example, by adjusting the etching process parameters, the etching depth of the back etching operation is controlled to be smaller than the etching depth of the second etching operation.

After the back etching operation, an isolation material is filled in the first trench, the second trench, and the third trench to form the word line structure. Referring to FIG. 1A to FIG. 1C for the specific word line structures formed, the isolation material layers 114 can avoid conduction between adjacent active areas. In some embodiments, the isolation material may be silicon nitride, silicon oxynitride, silicon carbonitride or other suitable insulating materials.

After the word line structures are formed, a planarization process can be performed by chemical mechanical polishing (CMP). It is to be noted that, since a polishing rate of silicon nitride is lower than that of silicon or silicon oxide in CMP process, there will be a phenomenon that surfaces of the isolation material layers 114 are higher than a surface of the substrate due to a polishing selectivity ratio of CMP when the isolation material is silicon nitride, the active areas 10 are formed form silicon, and the isolation structure is formed form silicon oxide. In order to eliminate the uneven phenomenon caused by the polishing selection ratio of CMP, after the surface of the substrate is exposed by polishing by the CMP process, it is necessary to further etch back the isolation material layers 114, so that the surfaces of the isolation material layers in the word line structures are flush with the surface of the substrate.

In some embodiments, after the word line structures are formed, the surface of the semiconductor substrate is exposed, and then the semiconductor substrate is doped to form the sources and drains in the active areas at either side of the word line structures. Therefore, MOSFETs are formed. Further, the sources are connected to the bit lines. A storage capacitor is formed above a drain, and a lower plate of the storage capacitor is electrically connected to the drain. Thus, a semiconductor device, such as DRAM, and of course other types of semiconductor devices may be formed.

In the semiconductor device of the technical solution provided by the embodiments of the disclosure, the second sub-word line structures located in the second areas have the dimension in the second direction at least larger than that of the first sub-word line structures located in the first areas. Sectional areas of the word line structures with the shape increase, thereby reducing the resistance of the word line structures. Furthermore, because the word line structures are connect with the gates of the transistors, or the word line structures themself serve as the gates of the transistors of the semiconductor device, the reduction in the resistance of the word line structures is beneficial to increase switching efficiency of the transistors of the semiconductor device, optimizing reading and writing performance of the semiconductor device, thereby effectively improving the performance of the semiconductor memory device, and providing a possibility for higher integration of the storage cells.

It is to be understood that “an embodiment” or “some embodiments” referred to throughout the specification mean that particular features, structures or characteristics associated with the embodiment(s) are included in at least one embodiment of the disclosure. Therefore, the words “in an embodiment” or “in some embodiments” appearing throughout the specification do not necessarily refer to a same embodiment(s). In addition, these particular features, structures or characteristics may be incorporated in one or more embodiments in any suitable manner. It is to be understood that in the various embodiments of the disclosure, the serial numbers of the above-mentioned processes does not mean the sequence of execution, and the execution sequence of the processes shall be determined by its function and inherent logic, and shall not constitute any limitation on the implementation process of the embodiments of the disclosure. The above serial numbers of the embodiments in this disclosure are for description only, and do not represent the advantages and disadvantages of the embodiments.

The above is only the specific implementation modes of the disclosure, but the scope of protection of the disclosure is not limited thereto. Any change or substitution that is readily thought of by any technical person familiar with the technical field within the technical scope disclosed in the disclosure should be covered within the scope of protection of the disclosure. Therefore, the scope of protection of this disclosure shall be subject to the scope of protection of the claims.

What is claimed is:

1. A semiconductor device, comprising:
a semiconductor substrate, wherein a plurality of active areas are formed in the semiconductor substrate, and the plurality of active areas are isolated by an isolation structure, wherein the isolation structure comprises a plurality of first areas and a plurality of second areas, wherein a dimension of a given one of the plurality of second areas in a first direction is larger than a dimension of a given one of the plurality of first areas in the first direction; and
a plurality of word line structures located below a surface of the substrate and extending in the first direction, wherein the plurality of word line structures cross through the isolation structure and the plurality of active areas, a given one of the plurality of word line structures comprises a first sub-word line structure located in a given one of the first areas and a second sub-word line structure located in a given one of the second areas, wherein the first sub-word line structure has a first dimension in a second direction, the second sub-word line structure has a second dimension at least larger than the first dimension in the second direction, wherein an included angle is formed between the second direction and the first direction.

2. The semiconductor device according to claim 1, wherein in the second direction, a second sub-word line structure comprises a first portion having the first dimension and a second portion having the second dimension,
wherein the second portion is located above the first portion.

3. The semiconductor device according to claim 1, wherein a given one of the plurality of word line structures further comprises a third sub-word line structure located in a given one of the plurality of active areas;
wherein the third sub-word line structure has a third dimension less than or equal to the first dimension in the second direction.

4. The semiconductor device according to claim 3, wherein a depth of the third sub-word line structure is less than or equal to a depth of the first sub-word line structure, and the depth of the first sub-word line structure is less than a depth of the second sub-word line structure.

5. The semiconductor device according to claim 1, wherein the plurality of active areas are arranged alternatively and at intervals in the second direction, and the included angle between the first direction and the second direction is greater than 30 degrees.

6. The semiconductor device according to claim 1, wherein the plurality of first areas and the plurality of second areas are arranged alternately and at intervals in the first direction.

7. The semiconductor device according to claim 1, wherein a ratio of the second dimension to the first dimension is in a range of 1.2 to 3.

8. The semiconductor device according to claim 2, wherein a height ratio of the second portion to the first portion in a direction perpendicular to the substrate is in a range of 0.5 to 10.

9. A method for forming a semiconductor device, comprising:
providing a semiconductor substrate, wherein a plurality of active areas are formed in the semiconductor substrate, and the plurality of active areas are isolated by an isolation structure, wherein the isolation structure comprises a plurality of first areas and a plurality of second areas, wherein a dimension of a given one of the plurality of second areas in a first direction is larger than a dimension of a given one of the plurality of first areas in the first direction;
performing a first etching operation to form a first trench in the plurality of first areas and the plurality of second areas;
performing a second etching operation on the first trench in a given one of the plurality of second areas to widen an opening of the first trench so as to form a second trench, wherein the first trench has a first dimension in a second direction, and the second trench has a second dimension at least larger than the first dimension in the second direction; and
forming a word line structure in the first trench and the second trench, wherein the first direction is an extension direction of the word line structure, and an included angle is formed between the second direction and the first direction.

10. The method according to claim 9, wherein in the second direction, a second trench comprises a lower trench portion having the first dimension and an upper trench portion having the second dimension in communication with the lower trench portion.

11. The method according to claim 9, wherein the performing the first etching operation further comprises:
forming a third trench in a given one of the plurality of active areas, wherein the third trench has a third dimension less than or equal to the first dimension in the second direction.

12. The method according to claim 11, wherein a depth of the third trench is less than or equal to a depth of the first trench in a given one of the plurality of first areas, and the depth of the first trench in a given one of the plurality of first areas is less than a depth of the first trench in a given one of the plurality of second areas.

13. The method according to claim 11, wherein the performing the second etching operation on the first trenches in the second areas further comprises:
forming a patterned mask layer, wherein the patterned mask layer has a plurality of openings, a given one of which exposes a surface of a given one of the plurality of second areas and the first trench in the given one of the plurality of second areas; and
etching the first trench in the given one of the plurality of second areas along the given one of the plurality of openings to form the second trench in a given one of the plurality of second areas.

14. The method according to claim 13, wherein the forming the word line structures in the first trenches and the second trenches comprises:
forming a first liner and a second liner on inner walls of the first trench, the second trench and the third trench sequentially, and filling the first trench, the second trench and the third trench to form a conductive layer;
etching back the second liner and the conductive layer to remove part of the second liner and part of the conductive layer in the first trench, the second trench and the third trench, wherein an etching depth of the etching back is smaller than an etching depth of the second etching operation; and
filling an isolation material in the first trench, the second trench, and the third trench to form the word line structure.

15. The method according to claim 9, wherein the plurality of active areas are arranged alternatively and at intervals in the second direction, and the included angle between the first direction and the second direction is greater than 30 degrees.

16. The method according to claim 9, wherein the plurality of first areas and the plurality of second areas are arranged alternatively and at intervals in the first direction.

17. The method according to claim 9, wherein a ratio of the second dimension to the first dimension is in a range of 1.2 to 3.

18. The method according to claim 10, wherein a depth ratio of the upper trench portion to the lower trench portion in a direction perpendicular to the substrate is in a range of 0.5 to 10.
